(19) United States
(12) Patent Application Publication
(10) Pub. No.: US 2011/0031981 A1
(43) Pub. Date: Feb. 10, 2011

(54) VALUATION METHOD OF DIELECTRIC BREAKDOWN LIFETIME OF GATE INSULATING FILM, VALUATION DEVICE OF DIELECTRIC BREAKDOWN LIFETIME OF GATE INSULATING FILM AND PROGRAM FOR EVALUATING DIELECTRIC BREAKDOWN LIFETIME OF GATE INSULATING FILM

(75) Inventor: Shimpei Tsujikawa, Tokyo (JP)

Correspondence Address: SNR DENTON US LLP, P.O. BOX 061080, CHICAGO, IL, 60606-1080, US

(73) Assignee: SONY CORPORATION, Tokyo (JP)

(21) Appl. No.: 12/849,096

(22) Filed: Aug. 3, 2010

(30) Foreign Application Priority Data
Aug. 10, 2009 (JP) 2009-185966

(51) Int. Cl. G01R 31/12

(52) U.S. Cl. 324/554

(57) ABSTRACT

A valuation method of a dielectric breakdown lifetime of a gate insulating film for evaluating the dielectric breakdown lifetime of the gate insulating film of a MOS type element includes the steps of: deciding a Weibull slope of lifetime distribution until reaching a soft breakdown of the gate insulating film of the MOS type element; deciding a detection condition of the soft breakdown from the decided Weibull slope after the above step; and executing a dielectric breakdown test by using the decided detection condition.

### BACKGROUND OF THE INVENTION

1. Field of the Invention

The present invention relates to a valuation method of a dielectric breakdown lifetime of a gate insulating film, a valuation device of the dielectric breakdown lifetime of the gate insulating film and a program for evaluating the dielectric breakdown lifetime of the gate insulating film in a MOS type semiconductor element.

2. Description of the Related Art

Hitherto, a determination test of the dielectric breakdown lifetime of a gate insulating film has been performed for estimating the dielectric breakdown lifetime of the gate insulating film in a MOS type semiconductor element.

A determination test method of the dielectric breakdown lifetime of the gate insulating film in an integrated circuit including the MOS type semiconductor element will be explained as follows.

There is no definite rule on how to choose test elements (TEG: test element group) used for the dielectric breakdown lifetime test.

As general trends, a MOS structure element (a capacitor or a transistor) having a large area was used in related art, however, reduction of the area has been realized as the gate insulating film has become thinner. The reason why the reduction of the area is necessary is that gate leakage current per unit time is increased as the gate insulating film becomes thinner.

In Nicollian et al., International electron devices meeting 2000 (technical digest), p. 545-549 (Non-patent document 1), as an example indicating the area of the test element, gate insulating films of 1.7 to 4.3 nm are dealt with and test elements within a range of 10 μm² to 40004 μm² are used. The TDDB (Time Dependent Dielectric Breakdown) test is performed by using the test elements.

Temperature in the TDDB test, namely, the temperature of the MOS type semiconductor element during the TDDB test is set to be the temperature at which the lifetime is desired to be estimated. Normally, the higher the test temperature is, the shorter the dielectric breakdown lifetime is, therefore, the temperature is set to be the upper limit temperature of operation guarantee of the integrated circuit, typically, set to the vicinity of 80° C. to 150° C. in many cases.

It is normal to set plural points (three points or more) of voltages for the TDDB test within a time range in which dielectric breakdown of the gate insulating film to be tested can be actually measured. The reason of setting plural points of voltages is to acquire voltage dependence of the lifetime. The lifetime in the voltage actually used is calculated by extrapolation using the acquired voltage dependence.

The specific time range in which actual measurement is possible is typically one second to several dozen hours at longest.

In the dielectric breakdown test, a given voltage is applied to a gate voltage of the MOS type semiconductor element and gate current is measured at predetermined time intervals for evaluating insulation performance.

As the gate insulating film has become thinner in recent years, measurement of gate current is performed with a lower voltage than a stress voltage in many cases. Specifically, for example, even when the stress voltage is applied at 4V, measurement of gate current is performed at 1V or 1.5V. This is because monitoring of the gate current flowing at low voltage is more sensitive than monitoring at the stress voltage. This is widely known (for example, refer to Pompl et al., IEEE International reliability physics symposium 200 proceedings, p. 40-47 (Non-patent document 2)).

According to the above test method, for example, data as shown in FIG. 11 can be acquired. However, in the case of an extremely thin gate insulating film such as used in an advanced CMOS-LSI in recent years, loss of insulation performance is gradually generated, therefore, it is widely known that it is difficult to specify a dielectric breakdown point at a glance. For example, it is difficult to uniquely determine which point is determined as a generation point of the dielectric breakdown in points shown by plural arrows in FIG. 11.

A first sign of such unclear loss of insulation performance is called soft breakdown (SBD). Distribution parameters concerning periods of time until reaching the soft breakdown, namely, lifetimes of soft breakdown (63.2% lifetime in which a breakdown rate reaches 63.2% and the Weibull slope) are extremely important parameters when quantifying the dielectric breakdown lifetime.

Therefore, how to detect the unclear soft breakdown is extremely important when estimating the dielectric breakdown lifetime.

Methods of detecting the soft breakdown in related art are roughly divided into two types. Respective methods will be explained below.

One of the methods in related art is a method disclosed in Kaczer et al., International electron device meeting 2004 Technical digest, p. 713-716 (Non-patent document 3). This is the method in which attention is paid to the difference between gate current values adjacent in time series and the moment when the difference becomes higher than a given threshold is detected as the soft breakdown.

The other method in related art is a method using current noise, which is disclosed in Suchle et al., International reliability physics symposium 2000 proceedings, p. 33-39 (Non-patent document 4) and JP-A-2004-214235 (Patent Document 1). This is the method utilizing a phenomenon in which the gate current value becomes unstable after the soft breakdown, that is, the phenomenon in which current is remarkably increased or decreased to be recorded on the noise.

A concept of progressive breakdown (PBD) comes to be embraced when dealing with the TDDB of the extremely thin gate oxide film having a thickness of 2 nm or less (for example, refer to E. Y. Wu et al., International reliability physics symposium 2006 proceedings, p. 54-62 (Non-patent document 5) or A. Kerberet al., International reliability physics symposium 2007 proceedings, p. 217-220 (Non-patent document 6)).

The concept of the PBD will be explained below.

The process of reaching hard breakdown (HBD) at which the extremely thin gate oxide film lose insulation performance to a degree that will cause operation failures of the integrated circuit can be comprehended in two stages. That is, two stages are the above soft breakdown (SBD) which is an appearance of the first sign of dielectric breakdown and the phenomenon in which a breakdown point is grown and conductivity is increased (the above SBD) continued from the SBD.

As apparent from the above Non-patent document 5 and the above Non-patent document 6, the two phenomena which are the SBD and the PBD are independent phenomena respectively, therefore, the HBD causing the circuit operation failures can be calculated from distribution parameters of the SBD and the PBD.

It is known that a period of time until reaching the SBD, namely, a SBD lifetime follows the Weibull distribution. It is considered that a period of time necessary for the PBD, namely, a PBD time will follow the Weibull distribution (refer to Non-patent document 6).

Therefore, the HBD can be represented by the above distribution parameters, and probability in which the HBD is generated during a time “0” to a time “t” (referred to as cumulative probability) F_{HBD} is represented by the following formula.

$${F}_{HBD} ( t ) = {\int }_{0}^{t} {\int }_{0}^{{t}^{′}} {f}_{SBD} ( {t}^{″} ) {f}_{PBD} ( {t}^{′} - {t}^{″} ) d {t}^{″} d {t}^{′}$$

Generation probability density f_{HBD} of the HBD in the time “t” is time differential of F_{HBD}, which will be represented as follows.

$${f}_{HBD} ( t ) = {\int }_{0}^{t} {f}_{SBD} ( {t}^{′} ) {f}_{PBD} ( t - {t}^{′} ) d {t}^{′}$$

Here, f_{SBD}(t) and f_{PBD}(t) are probability density functions of the SBD and the PBD respectively, which can be represented as the following formulas when following the Weibull distribution.

$${f}_{SBD} ( t ) = \frac{{β}_{SBD}}{{t}_{63 SBD}} \times {( \frac{t}{{t}_{63 SBD}} )}^{{β}_{{SBD}^{- 1}}} \times exp \{ - {( \frac{t}{{t}_{63 SBD}} )}^{{β}_{SBD}} \}$$

$${f}_{PBD} ( t ) = \frac{{β}_{PBD}}{{t}_{63 PBD}} \times {( \frac{t}{{t}_{63 PBD}} )}^{{β}_{{PBD}^{- 1}}} \times exp \{ - {( \frac{t}{{t}_{63 PBD}} )}^{{β}_{PBD}} \}$$

Here, β_{SBD}, β_{PBD}, t_{63SBD} and t_{63PBD} are values called Weibull shape parameters, and β represents a slope of Weibull plots, which is called the Weibull slope. “t63” represents the time when the defective fraction is 63.2%, which is a parameter widely used when the Weibull distribution is described.

Accordingly, it is possible to perform numeric calculation of the distribution of the HBD based on the weibull shape parameters of the SBD and the PBD. An example of relation between respective failure times of SBD, PBD, HBD and later described Weibit is shown in FIG. 12.

As can be seen from FIG. 12, the slope on the side of lower probability in the HDB distribution is β_{SBD}+β_{PBD}, which can be comprehended by analysis, though the detailed explanation is omitted.

According to the above, the HBD lifetime on the lower probability side is particularly longer than the SBD lifetime in a large scale.

### SUMMARY OF THE INVENTION

The present inventors have recognized that a problem exists in determination of the soft breakdown in the related art. There is no definite method of determining the soft breakdown not unclearly.

In the method disclosed in Non-patent document 3, there is a fetal problem that there is no definite guideline concerning how to set a threshold in the method disclosed in the Non-patent document 3.

In the Non-patent document 3, values of the Weibull slope in the case that soft breakdown lifetimes when changing the threshold are expressed by the Weibull distribution are checked, and when the value of the Weibull slope is large such as 2 or more, it is regarded that the soft breakdown is overlooked and the threshold is too high. In the document, it is concluded that thresholds within a range in which values of the Weibull slope are almost constant are appropriate by gradually reducing the threshold.

However, it is obvious that there remains large redundancy in the above guideline, which depends on the sense of a person dealing with data.

The present inventors tried to apply the methods disclosed in the Non-patent document 4 and Patent document 1 to a case of an extremely thin gate insulating film having an equivalent oxide thickness (EOT) of 1.2 nm.

Then, there was no definite change of a noise amount to a degree that is disclosed in the documents and it was difficult to apply the methods to the gate insulating film having the above film thickness.

In the Non-patent document 4, the oxide film having a film thickness of 2.0 nm or more is dealt with, therefore, it is highly likely that it is difficult to apply the method to the film having the thickness of 1.2 nm.

In related art, the method of determining the soft breakdown was determined and statistical processing was performed to data by using the determination method to thereby calculate the Weibull distribution parameters of the soft breakdown, therefore, it was difficult to determine the parameters uniquely.

Thus, it is desirable to provide a valuation method of a dielectric breakdown lifetime of a gate insulating film, a valuation device of the dielectric breakdown lifetime of the gate insulating film and a program for evaluating the dielectric breakdown lifetime of the gate insulating film capable of deciding a determination condition of the soft breakdown uniquely.

A valuation method of a dielectric breakdown lifetime of a gate insulating film according to an embodiment of the invention is a valuation method for evaluating the dielectric breakdown lifetime of the gate insulating film of a MOS type element. The method includes the steps of deciding a Weibull slope of lifetime distribution until reaching a soft breakdown of the gate insulating film of the MOS type element and deciding a detection condition of the soft breakdown from the decided Weibull slope after the above step. The method further includes the step of executing a dielectric breakdown test by using the decided detection condition.

A valuation device of a dielectric breakdown lifetime of a gate insulating film according to an embodiment is a valuation device for evaluating the dielectric breakdown lifetime of the gate insulating film of a MOS type element. The valuation device includes a voltage supply unit supplying voltage to the MOS type element for giving electrical stress with respect to the MOS type element, a current measurement unit measuring leakage current flowing through the gate insulating film and a temperature holding unit holding a test element including the MOS type element to a room temperature or less.

A program for evaluating a dielectric breakdown lifetime of a gate insulating film according to another embodiment of the invention allows a computer to execute valuation procedures. The procedures for evaluation includes a procedure of deciding a Weibull slope of lifetime distribution until reaching a soft breakdown of the gate insulating film of a MOS type element and a procedures of deciding a detection condition of the soft breakdown from the decided Weibull slope after the above procedure. Additionally, procedure of executing a dielectric breakdown test by using the decided detection condition is further included.

According to the valuation method of the dielectric breakdown lifetime of the embodiment of the invention, the Weibull slope of life distribution until reaching the soft breakdown is decided and the detection condition of the soft breakdown is decided from the Weibull distribution. According to this, the detection condition of the soft breakdown can be decided uniquely as well as logically without being deviated.

Then, the dielectric breakdown test is executed by using the decided detection condition, thereby detecting the soft breakdown without missing the point.

According to the configuration of the valuation device of the embodiment of the invention, the leakage current can be measured by giving electrical stress to the MOS type element by the voltage supply unit supplying voltage to the MOS type element and the current measurement unit measuring leakage current flowing through the gate insulating film. According to this, it becomes possible to execute the dielectric breakdown test.

The valuation device includes the temperature holding unit holding the test element including the MOS type element to the temperature at the room temperature or less, therefore, the dielectric breakdown test can be performed at the room temperature or less. According to this, by using the temperature holding unit the dielectric breakdown test is executed at the room temperature or less to thereby decide the Weibull slope of lifetime distribution until reaching the soft breakdown more accurately.

According to the program for evaluating the dielectric breakdown lifetime of the embodiment of the invention, it is possible to allow a computer to execute the valuation method of the dielectric breakdown lifetime of the embodiment of the invention and the dielectric breakdown lifetime can be evaluated accurately in a short period of time.

According to the embodiment of the invention, the detection condition of the soft breakdown to be a basis on dealing with dielectric breakdown of the gate insulating film can be decided uniquely as well as logically, and the soft breakdown can be detected without missing the point.

Accordingly, it becomes possible to determine the dielectric breakdown lifetime appropriately according to the embodiment of the invention.

### BRIEF DESCRIPTION OF THE DRAWINGS

FIG. 1 is a graph showing variations of a Weibull slope of SBD lifetime distribution by changing a threshold of current variation;

FIG. 2 is a graph showing results obtained by calculating HBD distribution by a Monte Carlo simulation when “t₆₃” of SBD is 140 times as much as “t₆₃” of PBD;

FIG. 3 is a graph showing the relation between the standard deviation of the gate area and the actually-measured reduction amount of the Weibull slope, which have been calculated by the Monte Carlo simulation;

FIG. 4 is a graph showing the relation between the SBD lifetime, the PBD time and the temperature;

FIG. 5 is a graph showing the relation between the SBD lifetime, the PBD time and the gate voltage;

FIG. 6 is a graph showing HBD lifetime distribution calculated by actually-measured values;

FIG. 7 is a flowchart showing valuation procedures by a valuation method of a dielectric breakdown lifetime of a gate insulating film according to an embodiment of the invention;

FIG. 8 is a graph showing the relation between the gate area and the Weibull slope of HBD according to the embodiment of the invention;

FIG. 9 is a graph showing variations of the Weibull slope of the SBD lifetime distribution when changing the threshold of the current variation;

FIG. 10 is a graph showing data obtained by a dielectric breakdown test when a metal gate electrode is combined with a thin high-k gate insulating film;

FIG. 11 is a graph showing data obtained by the dielectric breakdown test;

FIG. 12 is a graph showing an example of the relation of respective failure times of SBD, PBD, HDB and Weibit; and

FIG. 13 is a schematic configuration diagram (block diagram) of a valuation device according to an embodiment of the invention.

### DESCRIPTION OF THE PREFERRED EMBODIMENTS

Hereinafter, a best mode for carrying out the invention (hereinafter, referred to as an embodiment) will be explained.

The explanation will be made in the following order.

1. Outline of the invention

2. Embodiment (Example)

### 1. Outline of the Invention

The present invention applies a procedure which is completely inverse to the procedure started from “determination of a standard for detecting the soft breakdown” and proceeding to “determination of the Weibull distribution parameters” in related art.

First, how to decide a determination condition of the soft breakdown will be explained based on the Non-patent document 3.

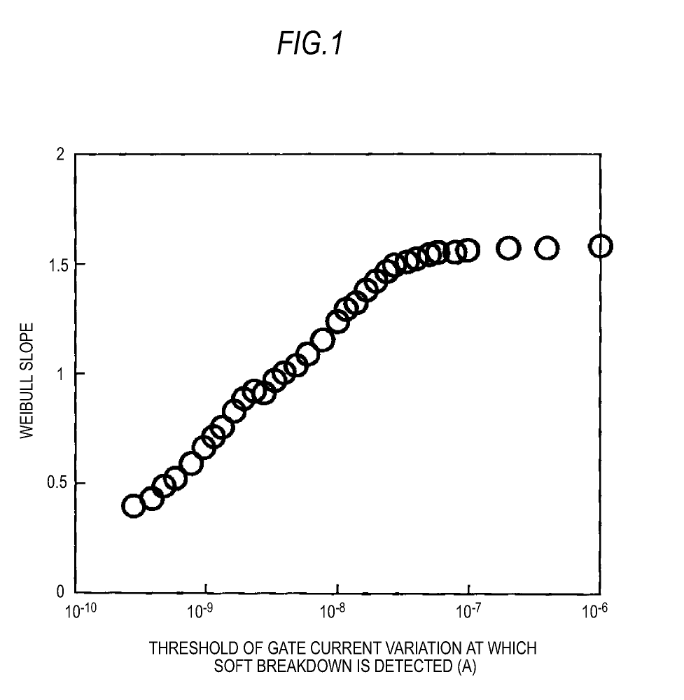

An example of checking variations of the Weibull slope of SBD lifetime distribution by changing the SBD determination condition, namely, a threshold of current variation will be shown in FIG. 1.

As can be seen from the result of FIG. 1, it is difficult to decide the SBD determination condition uniquely as described above.

Accordingly, in the embodiment of the invention, the Weibull slope of the SBD is calculated before deciding the determination standard of the soft breakdown as an inverse idea to the method of related art.

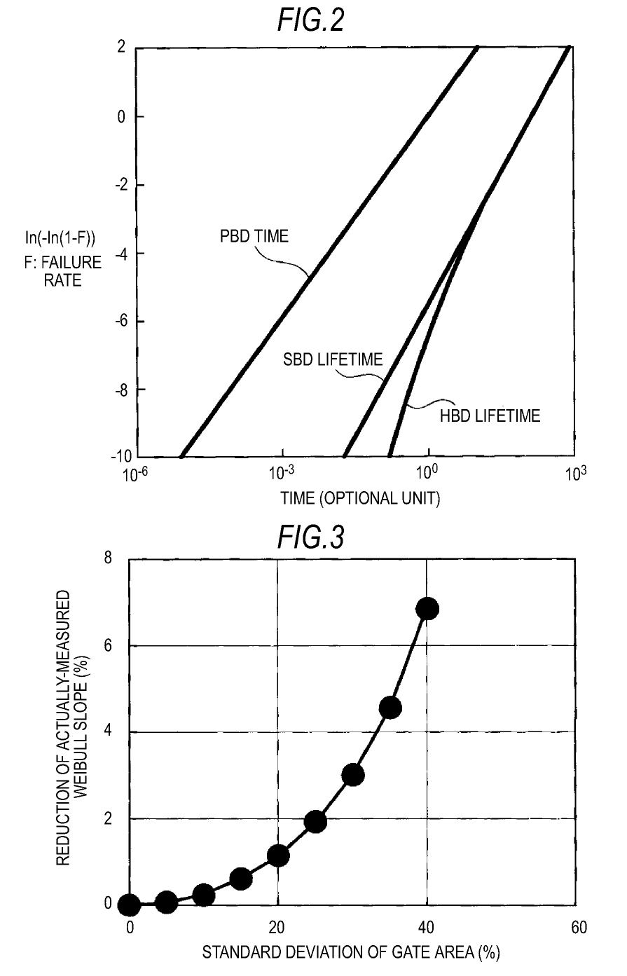

It is preferable that t_{PBD}<<t_{SBD} for deciding the Weibill slope of the SBD without getting nervous about the determination condition. For example, results obtained by calculating HBD distribution in the case where “t₆₃” of the SBD (t_{63SBD}) is 140 times as much as “t₆₃” of the PBD (t_{63PBD}) using a Monte Carlo simulation are shown in FIG. 2. Specific calculation parameters are as follows. Concerning the SBD, t_{63SBD} is 140 seconds and the Weibull slope is 1.11. Concerning the PBD, t_{63PBD} is 1 second and the Weibull slope is 0.84.

According to FIG. 2, in a range of 2 to −2 in a vertical axis of the Weibull plot (In(−In(1−F)) when the defective fraction is F, which is called Weibit), the HBD distribution and the SBD distribution almost overlap each other.

That is, when the HBD lifetime distribution which can be decided without room for doubt about the determination standard is calculated and the Weibull slope is calculated from data of an area in which Weibit is −2 or more, the slope can be regarded as the Weibull slope of the SBD lifetime distribution.

Here, according to the study of inventors, the following three points are effective for realizing the state of t_{PBD}<<t_{SBD}.

(1) Reduction of a gate area

(2) Reduction of temperature

(3) Reduction of voltage

Concerning the gate area in the above (1), it is effective because, when the gate area is reduced, t_{SBD} longer while t_{PBD} is almost constant.

However, when test elements having a small area are used for the TDDB valuation, there is a concern about effects on measurement results caused by variations of the gate area. Specifically, variations of the TDDB lifetime are increased due to the variations of the gate area, therefore, it is presumed that the Weibull slope of the SBD lifetime distribution calculated from actual measurement data will be reduced.

Accordingly, the effects of variations of the gate area of the TDDB test elements were estimated by the Monte Carlo simulation. The relation between the standard deviation of the gate area and the actually-measured reduction amount of the Weibull slope is shown in FIG. 3 as estimation results.

According to FIG. 3, it is seen that the effect to the actually-measured Weibull slope can be suppressed to 5% or less even when processing variation (standard deviation) of the gate area reaches 35% of the central value.

Effects by the processing variations in the most advanced process such as a 45 nm node to the actually-measured Weibull slope are simply estimated. The gate size which can be stably processed, namely, which can be used in an integrated circuit is, for example, 40 nm in gate length and 80 nm in gate width.

It is not so difficult that these processing variations of the gate area are suppressed to 5% or less in the standard deviations. In other words, it is not difficult to suppress the processing variations of the gate area to 10% or less in the standard deviations, therefore, the effects to values of the Weibull slope will be at the negligible level.

Accordingly, the processing variations have no problem when using the minimum size at which the processing can be performed for calculating the Weibull slope of the SBD distribution accurately, therefore, a MOS transistor having the smallest gate area within a range in which the processing can be performed should be prepared as the test element.

Concerning the temperature of the above (2), it is effective because temperature dependencies differ in t_{SBD} and t_{PBD} and that t_{SBD}÷t_{PBD} will be a large value at a lower temperature.

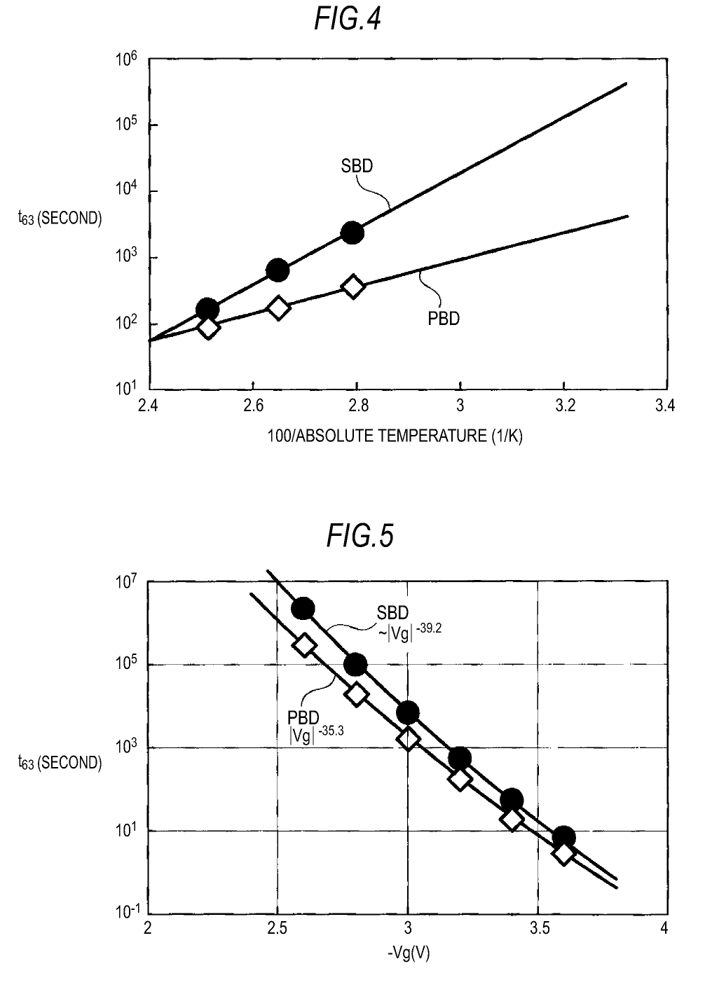

The relation between the SBD lifetime, the PBD time and the temperature will be shown in FIG. 4. A horizontal axis of FIG. 4 indicates 1000/absolute temperature, which becomes lower as proceeding to right.

As shown in FIG. 4, the temperature dependencies largely differ in the SBD lifetime and the PBD time, therefore, it is effective to reduce the test temperature.

It is normal that the TDDB test is performed at a high temperature considering the operation of the integrated circuit at the high temperature. On the other hand, in order to decide the Weibull slope of the SBD and the SBD determination standard, it is effective that the TDDB test is executed at a second temperature which is sufficiently lower than the temperature of the normal TDDB test (first temperature). Particularly, it is further effective that the TDDB test is executed at a room temperature or at a temperature lower than the room temperature.

Concerning the voltage of the above (3), it is effective because voltage dependencies differ in t_{SBD} and t_{PBD} and that t_{SBD}÷t_{PBD} will be a large value with a lower voltage.

The relation between the SBD lifetime, the PBD time and the gate voltage is shown in FIG. 5.

However, the difference of voltage dependencies between the SBD lifetime and the PBD time is not large, therefore, it is preferable that the test voltage is reduced in a possible range. The possible range in this case means the range in which the TDDB test can be completed in a realistic period, and the realistic period can be regarded as several days to several weeks at longest.

For example, it has been proved by the present inventors using Monte Carlo simulation that it is necessary to execute the TDDB test by breaking approximately 2600 pieces of test elements in order to decide the Weibull slope at ±5% accuracy as well as at 95.4% determinacy. In order to complete the test within, for example 100 hours when executing the TDDB test sequentially to 2600 pieces of test elements, it is necessary to set the voltage so that the test per one test element is completed in approximately 2 or 3 minutes.

Here, when a system or an valuation device in which probes are applied to plural test elements in a wafer to thereby simultaneously execute the test is constructed, the test can be executed with a lower voltage.

For example, if the TDDB tests of 40 elements can be simultaneously executed, it is possible to reduce the voltage to a degree that approximately 1.5 hours (=100 hours÷(2600÷40)) are necessary for the TDDB test of each element.

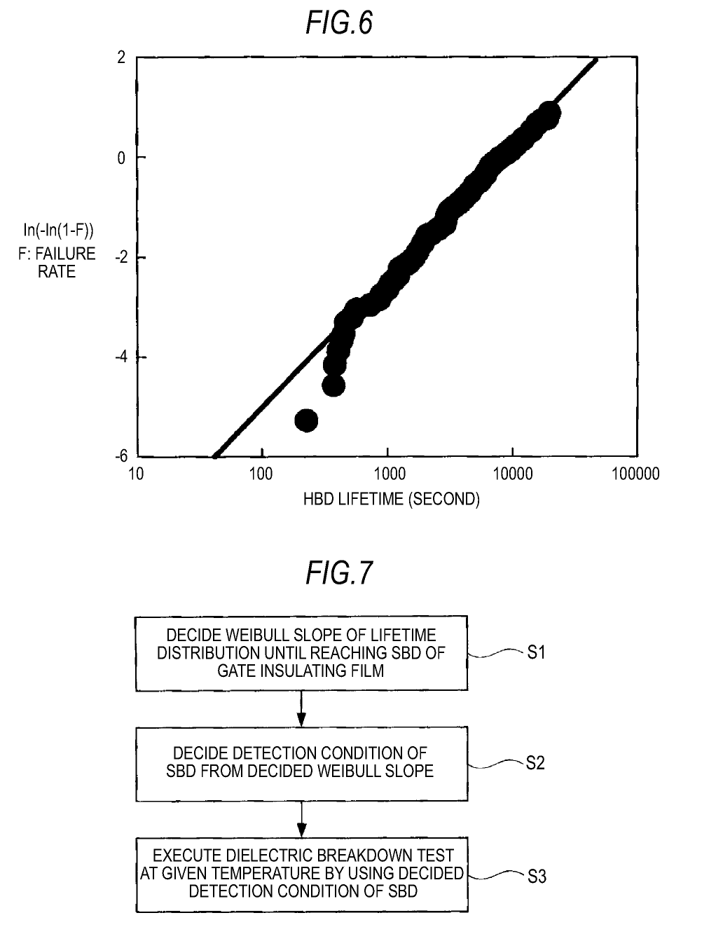

As an actual example, the TDDB lifetime in a pMOS, for example, having a SiON gate insulating film a film thickness of 1.2 nm was measured under conditions in which the stress gate voltage of −3.1V as well as the temperature of 25° C. by using test elements having a gate length of 40 nm and a gate width of 200 nm. The HBD lifetime distribution calculated by the measurement is shown in FIG. 6.

According to FIG. 6, lifetimes are on a straight line in a range of −3 or more in the Weibit, and lifetimes are gradually departed from the straight line when the Weibit becomes −3 or less. It can be seen that the result has a similar shape to the Monte Carlo simulation result of the HBD lifetime distribution in the case of t_{PBD}<<t_{SBD} shown in FIG. 2.

That is, it can be regarded that the area of the HBD lifetime distribution where the Weibit is large (for example, −2 or more) shown in FIG. 6 almost overlaps the SBD lifetime distribution, and it can be seen that the Weibull slope of the SBD can be decided from data of that area.

It is further difficult to realize the state of t<t_{PBD}<<t_{SBD} as the film thickness of the gate insulating film becomes thinner. This is reported in documents (for example, refer to Pompl et al., Microelectronics Reliability, Vol. 46, 2006, p. 1603-1607).

Therefore, when the gate insulating film is thinner than 1.2 nm, it is necessary to reduce the gate area of the test element or reduce the test temperature to the room temperature or less.

In the valuation method of the dielectric breakdown lifetime of the gate insulating film according to the embodiment of the invention, the Weibull slope of the lifetime distribution until reaching the soft breakdown of the gate insulating film of a MOS type element is decided.

After that, a detection condition of the soft breakdown is decided from the decided Weibull slope. The detection condition is, for example, a threshold of variation of leakage current.

Then, the dielectric breakdown test is performed by using the decided detection condition of the soft breakdown.

The Weibull slope of the lifetime distribution until reaching the soft breakdown is decided and the detection condition of the soft breakdown is decided from the Weibull slope, thereby deciding the detection condition of the soft breakdown uniquely as well as logically without being deviated.

The dielectric breakdown test is executed by using the decided detection condition, thereby detecting the soft breakdown without missing the point.

In the evaluation method according to the embodiment of the invention, a specific technique, procedure and so on for deciding the Weibull slope of the lifetime distribution until reaching the soft breakdown of the gate insulating film can be executed in accordance with the above explanation.

In the valuation method according to the embodiment of the invention, it is preferable to use test elements having the small gate area when deciding the Weibull slope of lifetime distribution until reaching the soft breakdown.

More preferably, the MOS type elements having a gate length and a gate width substantially equivalent to the minimum sizes used in a target integrated circuit are used as test elements.

The Weibull slope of the lifetime distribution until reaching the soft breakdown is decided by using the MOS type elements substantially equivalent to the minimum size used in the integrated circuit as test elements, thereby deciding the Weibull slope of lifetime distribution more accurately.

In the valuation method according to the embodiment of the invention, when deciding the Weibull slope of lifetime distribution until reaching the soft breakdown, it is preferable to execute the dielectric breakdown test at a temperature lower than the given TDDB test temperature, namely, the temperature condition at which the TDDB lifetime is estimated. More preferably, a temperature sufficiently lower than the given TDDB test temperature (for example, the above mentioned 80 to 150° C.), namely, for example, a temperature almost equivalent to the room temperature or lower than the room temperature is applied.

The Weibull slope of the lifetime distribution until reaching the soft breakdown is decided by executing the dielectric breakdown test at the temperature lower than the TDDB test temperature, thereby deciding the Weibull slope of lifetime distribution more accurately.

The valuation method of the dielectric breakdown lifetime of the gate insulating film according to the embodiment of the invention can be executed by using a valuation device having the same configuration as the valuation device used in the valuation method of related art.

The valuation device at least includes a voltage supply unit supplying voltage to the MOS type element for giving electrical stress to the MOS type element and a current measurement unit measuring leakage current flowing through the gate insulating film.

As the voltage supply unit, a power source, wiring, a terminal electrically connected to the MOS type element and so on can be included.

As the current measurement unit, an ampere meter, wiring, a terminal electrically connected to the MOS type element and so on can be included.

It is also preferable that the valuation device further includes a mechanism for fixing the test element including the MOS type element, a substrate including test elements and the like, a control unit controlling operation of the evaluation device, a processing unit processing data of the measured leakage current and so on.

In the case where the dielectric breakdown test is executed at the room temperature or less when deciding the Weibull slope of lifetime distribution until reaching the soft breakdown as described above, it is preferable to use a valuation device further including a temperature holding unit holding the test element including the MOS type element to the room temperature or less.

The valuation device of the dielectric breakdown lifetime of the gate insulating film according to the embodiment of the invention further includes such temperature holding unit in addition to the above voltage supply unit and the current measurement unit. According to the configuration, the dielectric breakdown test is executed at the room temperature or less by utilizing the temperature holding unit, thereby deciding the Weibull slope of lifetime distribution until reaching the soft breakdown more accurately.

Moreover, the valuation device according to the embodiment of the invention can apply a configuration in which the voltage supply unit can give electrical stress to plural pieces of test elements formed on the substrate at the same time as well as the current measurement unit can perform measurement with respect to plural test elements.

According to such configuration, leakage current of plural test elements can be measured, as a result, the dielectric breakdown test can be executed with respect to plural test elements in a shorter period of time. Additionally, the test can be executed with lower voltage as described above.

A program for evaluating the dielectric breakdown lifetime of the gate insulating film according to the embodiment of the invention allows a computer to execute the following procedures.

(1) Procedure of deciding the Weibull slope of lifetime distribution until reaching the soft breakdown of the gate insulating film of the MOS type element

(2) Procedure of deciding the detection condition of the soft breakdown from the decided Weibull slope after the above procedure

(3) Procedure of performing the dielectric breakdown test by using the decided detection condition

That is, the program according to the embodiment of the invention allows the computer to execute the above valuation method of the dielectric breakdown lifetime of the gate insulating film.

According to the program for evaluating the dielectric breakdown lifetime of the embodiment of the invention, the valuation method of the dielectric breakdown lifetime of the embodiment of the invention is allowed to be executed by the computer. The dielectric breakdown lifetime can be evaluated accurately in a short period of time.

Here, a flowchart of the valuation method of the dielectric breakdown lifetime of the gate insulating film according to the embodiment of the invention is shown in FIG. 7.

First, in Step S1, the Weibull slope of the lifetime distribution until reaching the SBD (soft breakdown) of the gate insulating film is decided.

Next, in Step S2, the detection condition of the SBD (soft breakdown) is decided from the decided Weibull slope of lifetime distribution until reaching the SBD (soft breakdown).

Next, in Step S3, the dielectric breakdown test is executed at a given temperature by using the decided detection condition of the SBD (soft breakdown).

The valuation of the dielectric breakdown lifetime of the gate insulating film can be executed as the above.

The program for evaluating the dielectric breakdown lifetime of the gate insulating film according to the embodiment of the invention allows the computer to execute processing of the flowchart shown in FIG. 7.

In the embodiment of the invention, both a p-MOS and an n-MOS can be applied as the MOS type element.

### 2. Embodiment (Example)

Next, a specific embodiment (example) of the invention will be explained.

In the present embodiment (example), a gate electrode is made of polysilicon and a gate insulating film is made of a SiON film having a film thickness of 1.2 nm in a p-MOS transistor.

An example of a procedure of calculating a TDDB lifetime of the gate insulating film of the p-MOS transistor according to the embodiment of invention will be explained as follows.

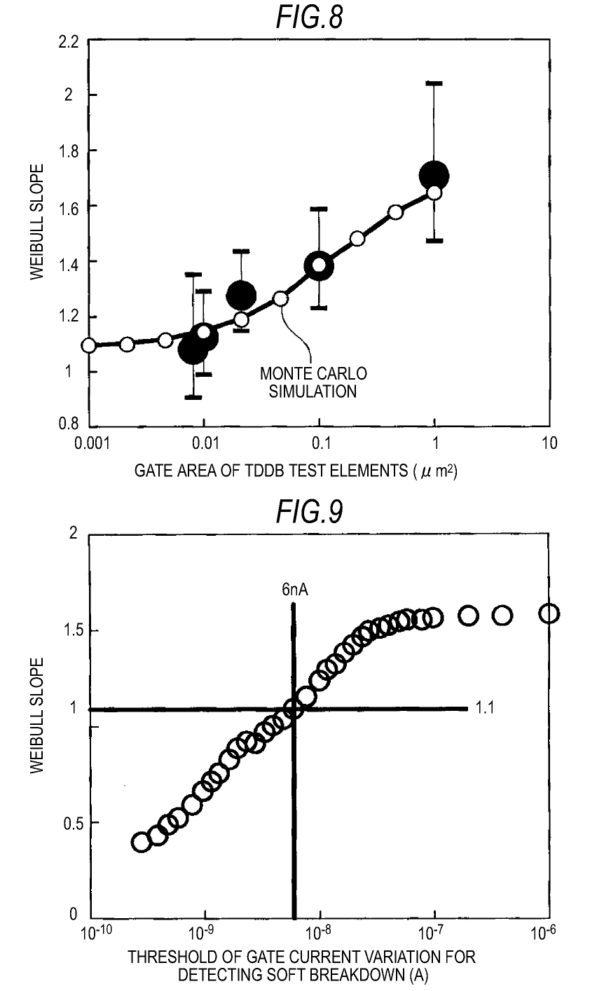

First, in order to decide the Weibull slope of the SBD lifetime, the Weibull slopes of the HBD lifetime were obtained by performing the TDDB test with respect to test elements having various types of gate areas. The relation between the gate area and the Weigull slope as the result of the above is shown in FIG. 8.

The details of test conditions were decided so as to estimate the Weibull slope of the SBD as accurate as possible, that is, the test temperature was set to 25° C. and data used for calculating the Weibull slope was within an area of −2 or more in the Weibit.

Under the above conditions, it was considered that the Weibull slope of the HBD in a sufficiently small area corresponded to that of the SBD.

Actual measurement results of the Weibull slopes of the HBD are shown by marks “” in FIG. 8. At the same time, 95.4% confidential intervals are shown by error bars. The 95.4% confidential interval was determined by Monte Carlo simulation, which mainly depended on the number of elements broken at the TDDB test. Marks “∘” in FIG. 8 indicate the Weibull slopes of the HBD calculated by the Monte Carlo simulation, which are results of post verification obtained by modeling the dielectric breakdown phenomena based on a true value of the Weibull slope of the SBD lifetime distribution calculated from data points of FIG. 8.

According to results of two points at which the gate areas are 0.008 m² and 0.01 m², the true Weibull slope of the SBD was decided as 1.1. The HBD lifetime distribution concerning 0.01 m² is the one shown in FIG. 6, which is appropriate as the HBD distribution in the case of t<t_{PBD}<<t_{SBD} as has been described above.

Next, the determination condition of detecting the SBD is decided.

The Weibull slopes of the SBD lifetime with respect to various SBD determination conditions were calculated by performing the TDDB test at the stress gate voltage of −3.2V in 105° C. by using a large number of test elements, namely, 521 pieces, having a gate length of 40 nm and a gate width of 0.5 m. The result is shown in FIG. 9. Data shown in FIG. 9 is cited again as a different drawing for explanation, though it is the same data as the one already shown in FIG. 1.

Here, the true value of the Weibull slope of the SBD lifetime distribution has been calculated as 1.1, therefore, a threshold of gate current variation for detecting the SBD can be calculated as 6 nA.

The threshold of the gate current variation which is 6 nA means that the amount of the gate current increased with the SBD can be regarded as 6 nA, therefore, it can be applied also test elements having other gate areas.

The phenomena such as the SBD and the PBD are modeled by the known method shown in the Non-patent document 5 and the Non-patent document 6 by using the SBD determination standard decided as described above. Accordingly, the lifetime until reaching the failure of the integrated circuit due to dielectric breakdown of the gate oxide film, namely, the HBD lifetime can be estimated.

According to the above embodiment (example) of the invention, the TDDB test was performed at 25° C. before the TDDB test at the given temperature (105° C.) to calculate the Weibull slope of the SBD lifetime distribution, and the threshold of the gate current variation for detecting the SBD was calculated based on the Weibull slope. Accordingly, the threshold of the gate current variation for detecting the SBD, namely, the detection condition of the SBD can be decided uniquely as well as logically without being deviated.

Then, the TDDB test was performed by using the decided detection condition of the SBD. Accordingly, it is possible to detect the SBD without missing the point.

Additionally, the Weibull slope of the SBD lifetime was calculated under the conditions in which the test temperature was approximately room temperature of 25° C. and the test elements having small gate areas of 0.008 m₂ and 0.01 m₂ were used, thereby deciding the Weibull slope of the lifetime distribution more accurately.

In the above example, the embodiment of the invention was applied to the p-MOS transistor having the extremely-thin SiON gate insulating film having the thickness of approximately 1.2 nm and the gate electrode made of polysilicon.

The invention can be applied not only to the p-MOS transistor but also to the n-MOS transistor in the same manner.

In the case of the n-MOS transistor, the PBD time tended to be shorter than the case of the p-MOS transistor.

That is, in the range of study by the present inventors, the result of satisfying t<t_{PBD}<<t_{SBD} was obtained also in the n-MOS in the same manner when using test elements and the temperature condition whereby t_{PBD}<<t_{PBD} was satisfied and the Weibull slope of the SBD lifetime can be decided in the p-MOS. Accordingly, it is possible to decide the Weibull slope of the SBD lifetime also in n-MOS transistor.

In the above example, the SiON film was used as the gate insulting film, however, the invention can be also applied to MOS type elements using other gate insulating films such as a SiO₂ film and a SiN film.

Furthermore, it is difficult to conclude in general whether the technique of the invention is effective to high-dielectric constant gate insulating film (high-k gate insulating film) or a metal gate electrode, mass production of which has been already applied to the most-advanced MOS products. The mechanism of the gate dielectric breakdown generated when these new techniques are used has not been cleared yet and the breakdown mechanism may be changed according to the manufacturing method.

When the metal gate electrode is used, unmistakable dielectric breakdown occurs at a moment without showing so-called behavior lose to the PBD. This is reported to documents (for example, refer to Kauerauf et al., IEEE ELECTRON DEVICE LETTERS, VOL. 26, No. 10, OCTOBER 2005, p. 773)

It is considered that the technique of the embodiment of the invention is not necessary in this case.

However, as a result of study by the present inventors, it was found that, even when the metal gate electrode was used, such vivid dielectric breakdown did not occur in the case where the metal gate electrode was combined with an extremely thin high-k gate insulating film having the equivalent oxide thickness of 0.9 nm.

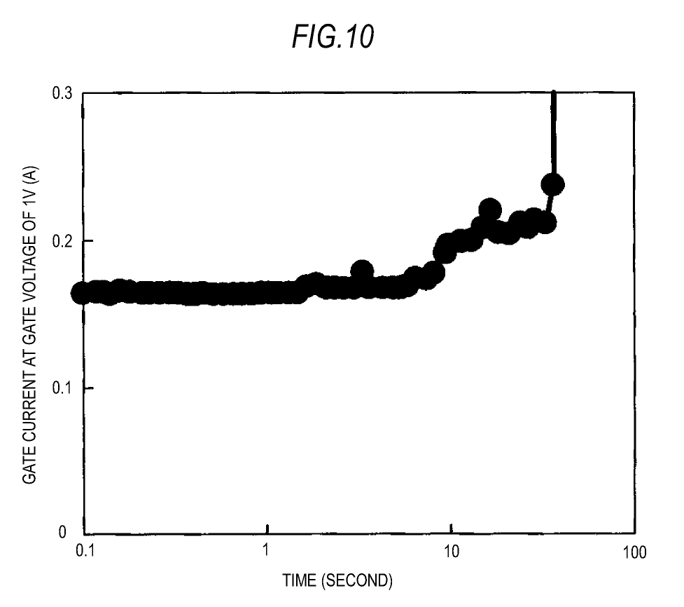

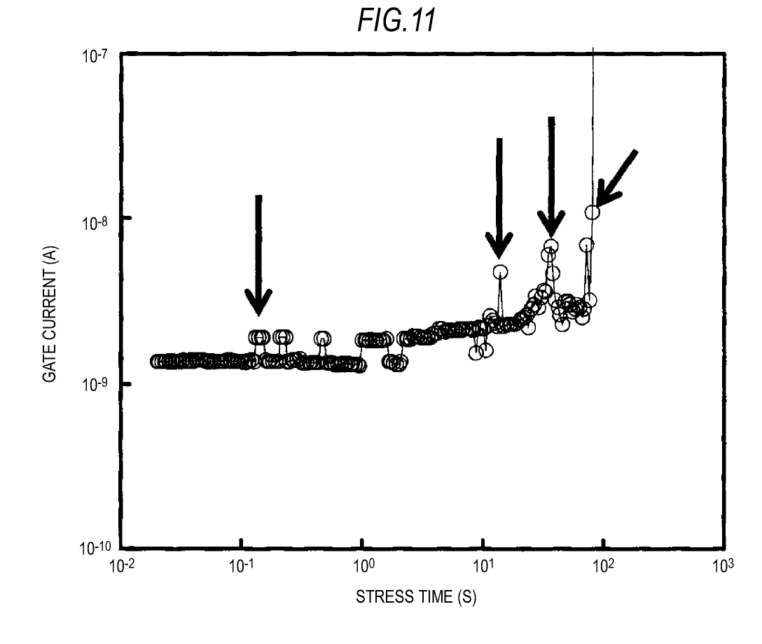

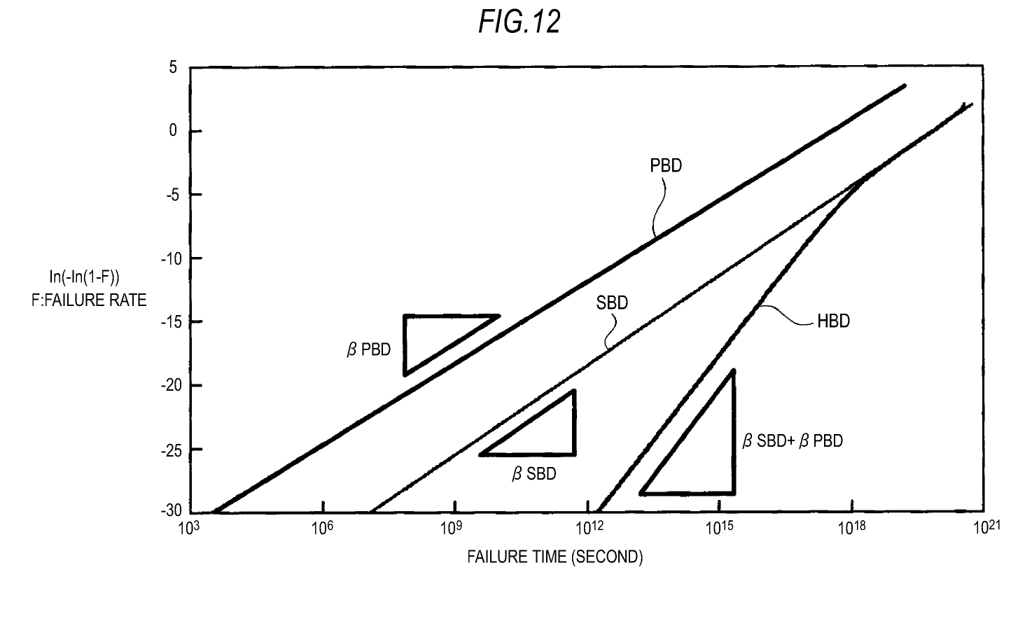

Data obtained by the dielectric breakdown test in this case is shown in FIG. 10.

As shown in FIG. 10, data similar to the case of using the extremely-thin SiON gate insulating film and the polysilicon gate electrode was obtained, in which it was difficult to determine the SBD uniquely. In this case, the technique according to the embodiment of the invention is considered to be effective.

Subsequently, a valuation device according to a specific embodiment of the invention will be explained.

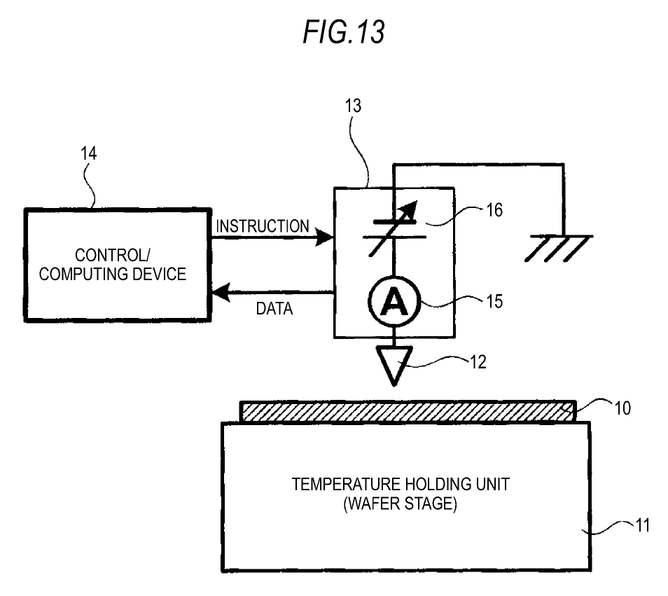

A schematic configuration diagram (block diagram) of the valuation device according to the embodiment of the invention is shown in FIG. 13.

The valuation device shown in FIG. 13 includes a temperature holding unit (wafer stage) 11 holding the temperature of a test wafer 10, a current measurement unit 13 measuring leakage current and a control/computing device 14 controlling the current measurement unit 13. The current measurement unit 13 is provided with a probe 12 for measurement at the tip thereof as well as an ampere meter 15 and a variable power source 16 at the inside thereof.

In the test wafer 10, a MOS type element is formed though not shown.

The valuation device includes a voltage supply unit supplying voltage to the MOS type element for giving electrical stress with respect to the MOS type element in the test wafer 10. The voltage supply unit is configured by the probe 12 and the variable power source 16 provided in the current measurement unit 13, an electrode electrically connected to the MOS type element in the test wafer 10 and the like.

The control/computing device 14 gives instructions for measurement to the current measurement unit 13. Then, data measured by the current measurement unit 13 is transmitted from the current measurement unit 13 to the control/computing device 14 to be computed therein. The control/computing device 14 may be configured so that a program for evaluating the dielectric breakdown lifetime of the gate insulating film according to the embodiment of the invention is executed therein.

The temperature holding unit (wafer stage) 11 includes a cooling mechanism and so on for holding the test wafer 10 including the MOS type element to a temperature at the room temperature or less. A specific configuration of the cooling mechanism is not particularly limited and a known configuration in related art can be used.

According to the configuration of the valuation device shown in FIG. 13, the electrical stress is given to the MOS type element in the test wafer 10 by the current measurement unit 13 and the voltage supply unit (the probe 12, the variable power source 16, the electrode on the side of the test wafer 10 and so on) to thereby measure the leakage current. The dielectric breakdown test can be executed in this manner. Additionally, the dielectric breakdown test can be executed at the room temperature or less by the temperature holding unit 11 including the cooling mechanism. According to this, the dielectric breakdown test is executed at the room temperature of less to thereby decide the Weibull slope of the lifetime distribution until reaching the soft breakdown more accurately.

In the valuation device shown in FIG. 13, it is also preferable that the voltage supply unit can give the electrical stress to plural pieces of test elements (including MOS type elements) formed on the substrate of the test wafer 10 at the same time. At this time, the current measurement unit 13 is configured to perform measurement with respect to plural pieces of test elements. For example, plural probes 12, plural ampere meters 15 and so on are provided. According to the configuration, leakage current of the plural pieces of test elements can be measured, therefore, the dielectric breakdown test can be executed with respect to plural pieces of test elements in a shorter period of time. It is also possible to execute the test with a lower voltage.

The invention is not limited to the above embodiment and can apply other various configurations within a scope not departing from the gist thereof.

The present application contains subject matter related to that disclosed in Japanese Priority Patent Application JP 2009-185966 filed in the Japan Patent Office on Aug. 10, 2009, the entire contents of which is hereby incorporated by reference.

What is claimed is:

1. A valuation method of a dielectric breakdown lifetime of a gate insulating film for evaluating the dielectric breakdown lifetime of the gate insulating film of a MOS type element comprising the steps of:
deciding a Weibull slope of lifetime distribution until reaching a soft breakdown of the gate insulating film of the MOS type element;
deciding a detection condition of the soft breakdown from the decided Weibull slope after the above step; and
executing a dielectric breakdown test by using the decided detection condition.

2. The valuation method of the dielectric breakdown lifetime of the gate insulating film according to claim 1,
wherein the MOS type element having the gate length and the gate width substantially equivalent to the minimum size used in a target integrated circuit is used in the step of deciding the Weibull slope.

3. The valuation method of the dielectric breakdown lifetime of the gate insulating film according to claim 1,
wherein, a test temperature in the step of executing the dielectric breakdown test is determined as a first temperature, and the Weibull slope is decided by performing the dielectric breakdown test at a second temperature lower than the first temperature in the step of deciding the Weibull slope.

4. The valuation method of the dielectric breakdown lifetime of the gate insulating film according to claim 3,
wherein the second temperature is determined as an approximately room temperature or as a temperature less than the room temperature.

5. A valuation device of a dielectric breakdown lifetime of a gate insulating film for evaluating the dielectric breakdown lifetime of the gate insulating film of a MOS type element comprising:
a voltage supply unit supplying voltage to the MOS type element for giving electrical stress with respect to the MOS type element;
a current measurement unit measuring leakage current flowing through the gate insulating film; and
a temperature holding unit holding a test element including the MOS type element to a room temperature or less.

6. The valuation device of the dielectric breakdown lifetime of the gate insulating film according to claim 5,
wherein the voltage supply unit has a configuration capable of giving the electrical stress with respect to plural pieces of test elements formed on a substrate, and the current measurement unit has a configuration capable of performing measurement with respect to the plural pieces of test elements.

7. A program for evaluating a dielectric breakdown lifetime of a gate insulating film allowing a computer to execute procedures of:
deciding a Weibull slope of lifetime distribution until reaching a soft breakdown of the gate insulating film of a MOS type element;
deciding a detection condition of the soft breakdown from the decided Weibull slope after the above procedure; and
executing a dielectric breakdown test by using the decided detection condition.
